(19) United States
(12) Patent Application Publication
(10) Pub. No.: US 2004/0218402 A1
(43) Pub. Date: Nov. 4, 2004

(54) Liquid-ornamented article having an illuminating structure

(76) Inventor: Chzh-Lin Jao, San Wan Country (TW)

Correspondence Address: TROXELL LAW OFFICE PLLC, SUITE 1404, 5205 LEESBURG PIKE, FALLS CHURCH, VA, 22041, US

(21) Appl. No.: 10/428,131

(22) Filed: May 2, 2003

(51) Int. Cl. F21V 7/04; H01L 33/00

(52) U.S. Cl. 362/555

(57) ABSTRACT

An article includes at least one closed chamber made of a transparent plastic material by way of injection molding and supersonic welding for containing at least one type of liquid and/or floating ornament; and an illuminating structure including a plurality of light-conducting bodies fixedly provided in the closed chamber with one end pressed against an inner surface of a wall portion of the closed chamber, and a light-emitting device mounted in a base that is connected to an outer side of the closed chamber corresponding to the light-conducting bodies. The light-emitting device includes a plurality of light-emitting diodes (LEDs) that may be conveniently turned on via a vibration or sound actuated switch to emit light for projecting into the light-conducting bodies via one end thereof and producing luminous spots or surfaces thereon, so as to create a unique decorating effect on the article.

### FIELD OF THE INVENTION

The present invention relates to a liquid-ornamented article having an illuminating structure. The article includes a transparent closed chamber for containing a liquid ornament therein; and the illuminating structure includes a plurality of light-conducting bodies, such as light-pervious plastic pipes or plastic optical fibers, fixed in the closed chamber with one end pressed against a wall of the chamber, and a plurality of light-emitting diodes (LEDs) located outside the closed chamber at positions corresponding to the light-conducting bodies. Light emitted from the LEDs is projected into the light-conducting bodies via one end thereof to produce luminous spots or surfaces in the closed chamber, forming a unique decoration for the article.

### BACKGROUND OF THE INVENTION

A lot of lavatory articles, such as milky lotion bottle, tooth glass, toothbrush holder, brush, mirror holder, and comb, and stationery items, such as penholder, paperweight, pen, and pencil case, as well as many other items, such as clock base, mobile phone holder, and mouse, have been provided on a main body thereof with a transparent closed chamber for containing an amount of mono-liquid or dual-liquid, and/or floating ornaments to create a decorating effect for the articles. While the liquid ornament has become a widely known skill, it gradually loses its appeal to consumers. One way to improve and make the conventional liquid ornament attractive to consumers is to provide it with a luminous effect in a simple and cost-effective manner.

### SUMMARY OF THE INVENTION

A primary object of the present invention is to provide a liquid-ornamented article having an illuminating structure. To achieve the above and other objects of the present invention, light-conducting bodies, such as light-pervious plastic pipes or plastic optical fibers, are fixed in a closed chamber on an article for containing the liquid ornament, such that an end of the light-conducting bodies are pressed against one transparent wall of the closed chamber, and a plurality of LEDs included in a light-emitting device are located at an outer side of the closed chamber to separately align with the ends of the light-conducting bodies pressed against the wall of the closed chamber. When the LEDs are turned on, light emitted therefrom is projected onto the ends of the light-conducting bodies to produce luminous spots or surfaces on different positions on the light-conducting bodies, creating a unique decorating effect on the liquid-ornamented article.

In the present invention, the liquid-ornamented article is preferably a bottle, a cup, or anything that has a base adapted for stably positioning on a flat surface, and may include, for example, lavatory articles, such as milky lotion bottle, tooth glass, toothbrush holder, brush, mirror holder, and comb; stationery items, such as penholder, paperweight, pen, and pencil case; and many other items, such as clockbase, mobile phone holder, and mouse.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a liquid-ornamented milky lotion bottle having an illuminating structure according to a first embodiment of the present invention;

FIG. 1A shows the liquid-ornamented milky lotion bottle of FIG. 1 in use;

FIG. 1B is an exploded perspective view of FIG. 1;

FIG. 1C is a fragmentary and enlarged sectional view of FIG. 1A;

FIG. 2 is a perspective view of a liquid-ornamented tooth glass having an illuminating structure according to a second embodiment of the present invention;

FIG. 2A is an exploded perspective view of FIG. 2 with the liquid ornament and the illuminating structure omitted from the drawing;

FIG. 2B is a fragmentary and enlarged sectional view of FIG. 2;

FIG. 3 is an exploded perspective view of a liquid-ornamented milky lotion bottle having an illuminating structure according to a third embodiment of the present invention; and

FIG. 3A is a fragmentary and enlarged sectional view of the milky lotion bottle of FIG. 3 in use.

### DETAILED DESCRIPTION OF THE PREFERRED EMBODIMENTS

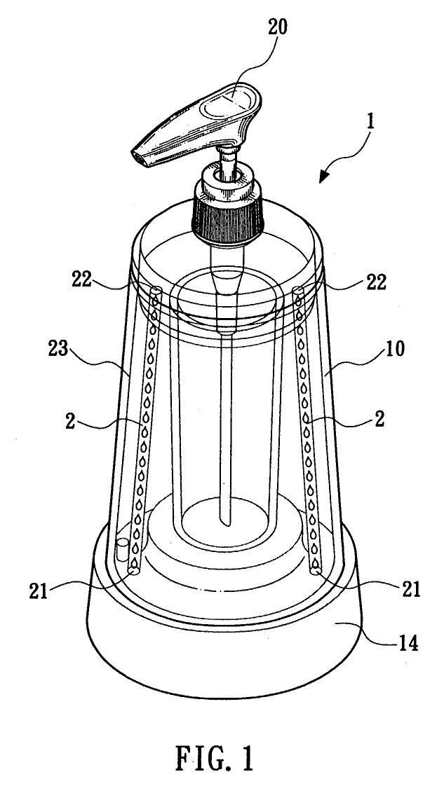

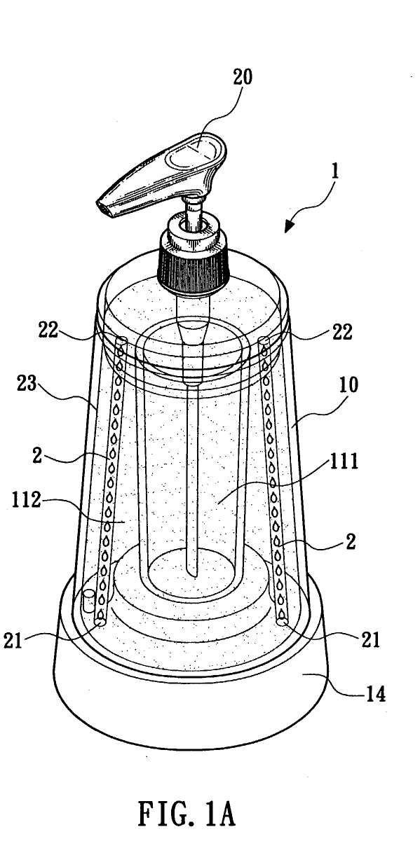

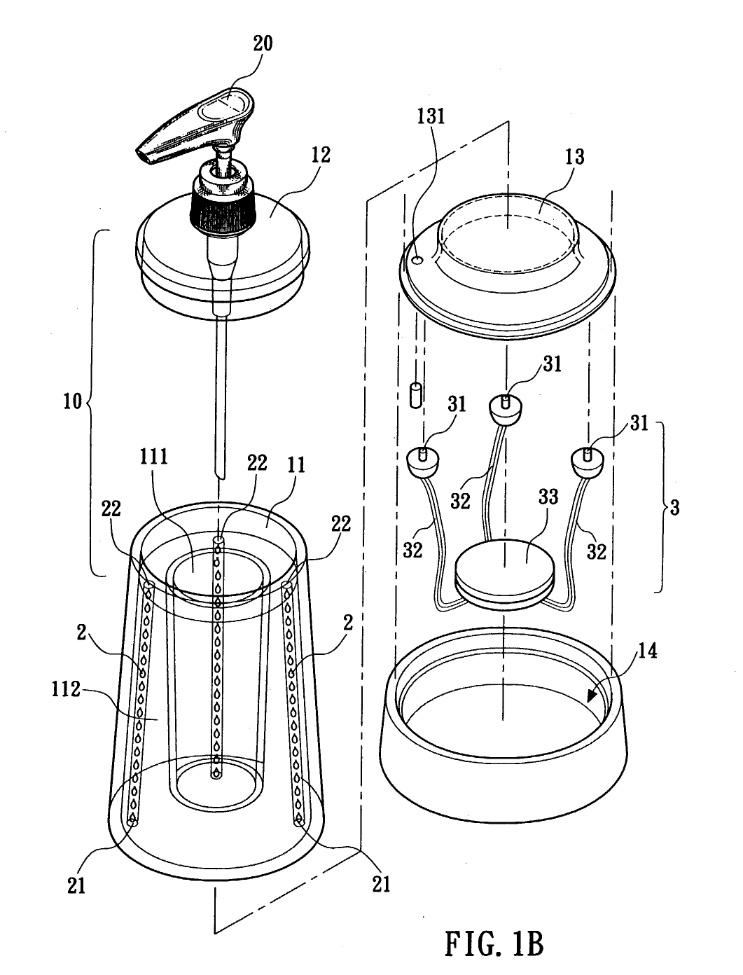

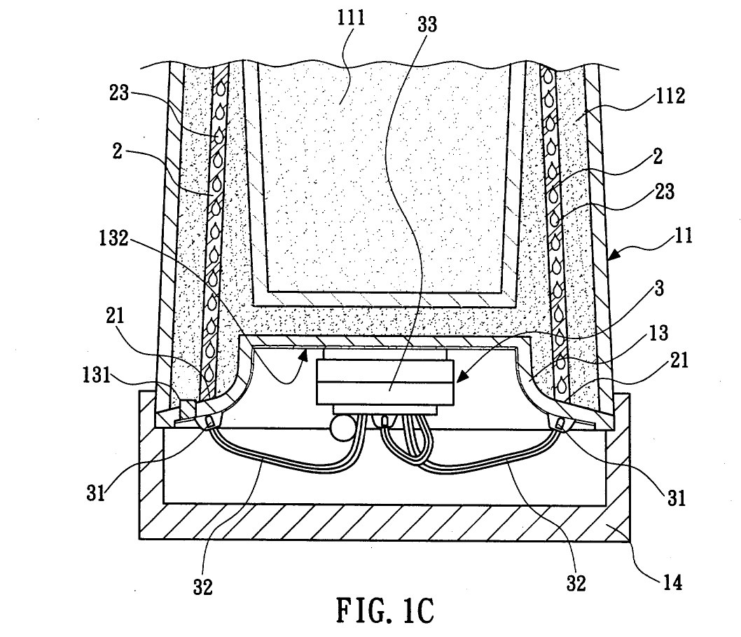

Please refer to FIGS. 1, 1A, 1B, and 1C in which a liquid-ornamented milky lotion bottle 1 having an illuminating structure according to a first embodiment of the present invention is shown. For the purpose of simplicity, the liquid-ornamented milky lotion bottle 1 will be referred to as the milky lotion bottle 1 hereinafter. As shown, the milky lotion bottle 1 mainly includes a container 10 and a squeezing head 20. The container 10 includes a body 11, a top cap 12, and a bottom cover 13, all of which are made of a transparent plastic material, such as acrylic resin, by way of integral injection-molding. The body 11 has a separated inner chamber 111 for receiving an amount of milky lotion therein and communicating with the squeezing head 20, so that the milky lotion in the inner chamber 111 may be dispensed for use via the squeezing head 20. The bottom cover 13 is connected to the body 11 by way of supersonic welding to seal an open bottom of the body 11, so that a space in the body 11 surrounding the inner chamber 111 forms an outer chamber 112 for receiving an amount of mono-liquid or dual-liquid and/or some floating ornaments therein. The bottom cover 13 is provided at a predetermined position with a filling opening 131, via which a desired type of liquid is supplied into the outer chamber 112. The milky lotion bottle 1 is characterized in that it includes an illuminating structure.

The illuminating structure includes a plurality of light-conducting bodies 2, such as light-pervious plastic pipes, upper ends of which are connected to predetermined positions on a top inner side of the outer chamber 112, and lower ends 21 of which are faced downward to correspondingly press against a bottom inner side of the transparent bottom cover 13; and a light-emitting device 3 consisting of a plurality of light emitting diodes (LED) 31 and corresponding conductors 32, and other related electronic elements 33, including, for example, a switch, a circuit board, etc. that are not particularly shown in the drawings. Abase 14 defining a space is connected to a lower side of the bottom cover 13 for receiving the light-emitting device 3 therein. The LEDs 31 may be of different colors, and the switch may be a vibration-actuated switch or a sound-actuated switch for turning on the LEDs 31. The electronic elements 33 may be differently designed to control modes in which the LEDs 31 operate. For example, the LEDs 31 may be turned off at a preset time, flash in a predetermined manner, etc. Since the design of the light-emitting device 3 with LEDs is a known skill, it is not discussed in details herein. In the present invention, the LEDs 31 in the base 14 are separately located right below the lower ends 21 of the light-conducting bodies 2, so that light emitted from the LEDs 31 is directly projected onto the light-conducting bodies 2 via the lower ends 21. Due to the light-conducting property of the light-conducting bodies 2, light projected onto the lower ends 21 also produces obvious luminous spots or surfaces on the light-conducting bodies 2, including upper ends 22 thereof. With the vibration-actuated or sound-actuated switch on the LED light-emitting device 3, a user is allowed to easily turn on the LEDs 31 for the same to emit light and thereby produce obvious, differently colored, and/or flashing luminous spots or surfaces on the milky lotion bottle 1, creating a unique and novel decorating effect for the bottle 1.

The light-conducting bodies 2 in the form of long pipes may be internally formed of a plurality of lengthwise arranged air bubbles 23 using the currently available plastic injection-molding technique. Light emitted from the LEDs 31 and projected onto the light-conducting bodies 2 would also produce luminous spots or surfaces on outer surfaces of the air bubbles 23 to create more changes in light on the light-conducting bodies 2.

Since the light-conducting bodies 2 are located in the outer chamber 112 above the bottom cover 13, and the LED light-emitting device 3 is located in the base 14 with the LEDs 31 and the lower ends 21 of the light-conducting bodies 2 separated from one another by the bottom cover 13, the light-conducting bodies 2 and the LED light-emitting device 3 may be set up to easily achieve the luminous decorating effect without affecting the manufacture of the milky lotion bottle 1 or causing any leakage problem at all. To avoid the LED light-emitting device 3 in the base 14 from being seen from the milky lotion bottle 1, a layer of opaque film 132 may be applied over an underside of the bottom cover 13, such that only areas on the bottom cover 13 corresponding to the lower ends 21 of the light-conducting bodies 2 and the LEDs 31 are kept transparent.

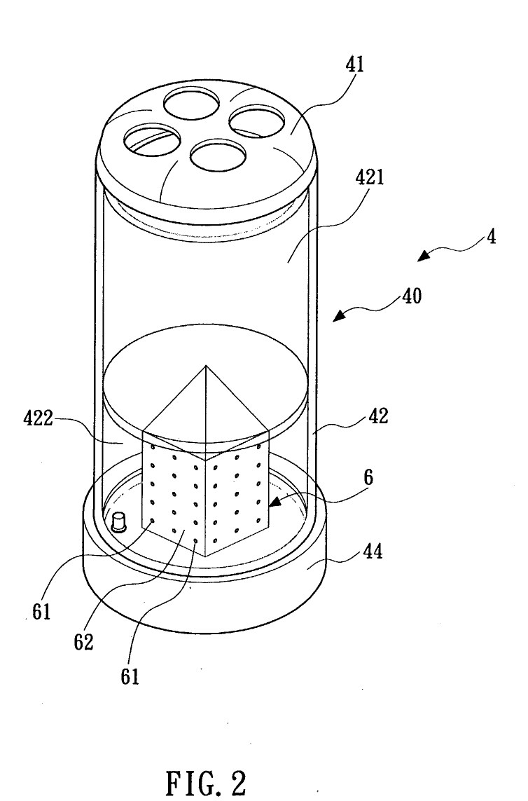

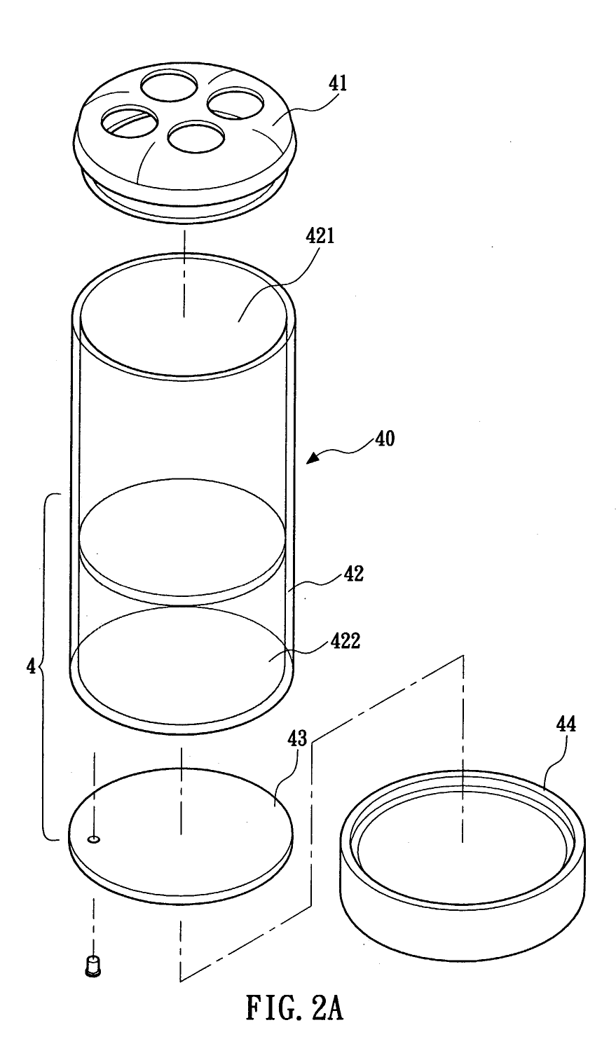

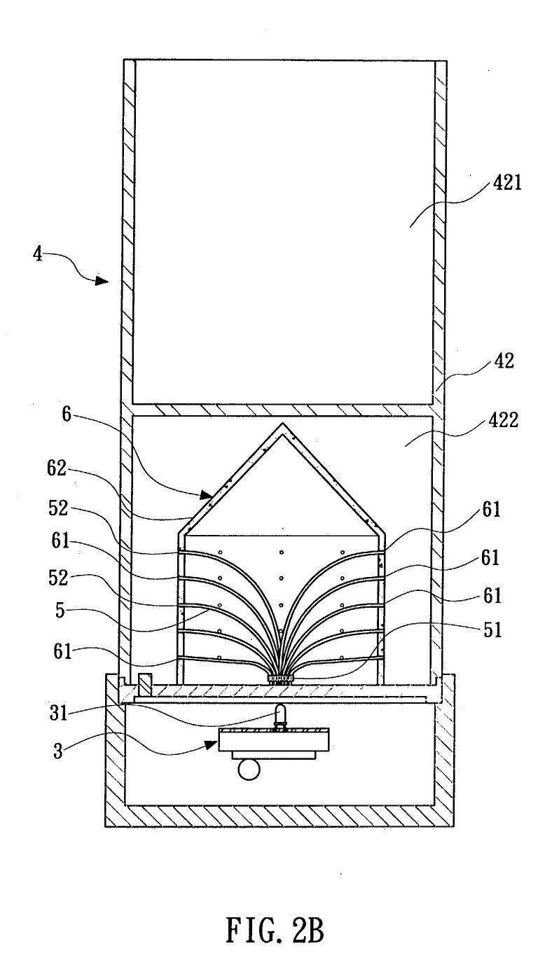

FIG. 2 shows a liquid-ornamented tooth glass 4 having an illuminating structure according to a second embodiment of the present invention. Please refer to FIG. 2A that is an exploded perspective view of the tooth glass 4. As shown, the tooth glass 4 includes a container 40 and a toothbrush holder 41 removably positioned onto a top opening of the container 40. The container 40 includes a body 42 and a bottom cover 43, both of which are made of a transparent plastic material, such as acrylic resin, by way of integral injection molding. The body 42 and the bottom cover 43 are then joined together through supersonic welding. An inner space of the body 42 is further divided into a closed lower chamber 422 for receiving an amount of mono-liquid or dual-liquid and/or some floating ornaments therein, and an open-topped upper chamber 421 for use as a general cup. The tooth glass 4 is characterized in that it includes an illuminating structure.

Please refer to FIG. 2B that is a sectional view of the tooth glass 4 having an illuminating structure as shown in FIG. 2. In the second embodiment of the present invention, the illuminating structure includes a plurality of light-conducting bodies 5 in the form of plastic optical fibers and located in the lower chamber 422; and a light-emitting device 3 including a light-emitting diode (LED) 31 and other related electronic elements (not shown) located in a base 44 connected to a lower side of the bottom cover 43 of the tooth glass 4. The plastic optical fibers 5 are tied together only at lower ends to form a bundle having a flat-headed end 51, so that upper ends 52 of the plastic optical fibers 5 may loosely stretch apart in different directions. The flat-headed end 51 of the plastic optical fibers 5 and the LED 31 of the light-emitting device 3 are respectively located at upper and lower side of the bottom cover 43 while they are separately aligned with each other. A hollow ornament 6 having a shell 62, which may be of any shape, is mounted in the lower chamber 422. The light-conducting bodies 5 are located in the ornament 6 with the upper ends 52 thereof separately exposed from holes 61 provided on the shell 62 of the hollow ornament 6. When the LED 31 is turned on, light emitted therefrom is directly projected onto the flat-headed lower end 51 of the bundle of the light-conducting bodies 5. Due to the light conducting property of the plastic optical fibers forming the light-conducting bodies 5, light projected onto the lower ends 51 also produces obvious luminous spots or surfaces at the upper ends 52 of the plastic optical fibers 5 to create a unique and novel decorating effect on the ornament 6.

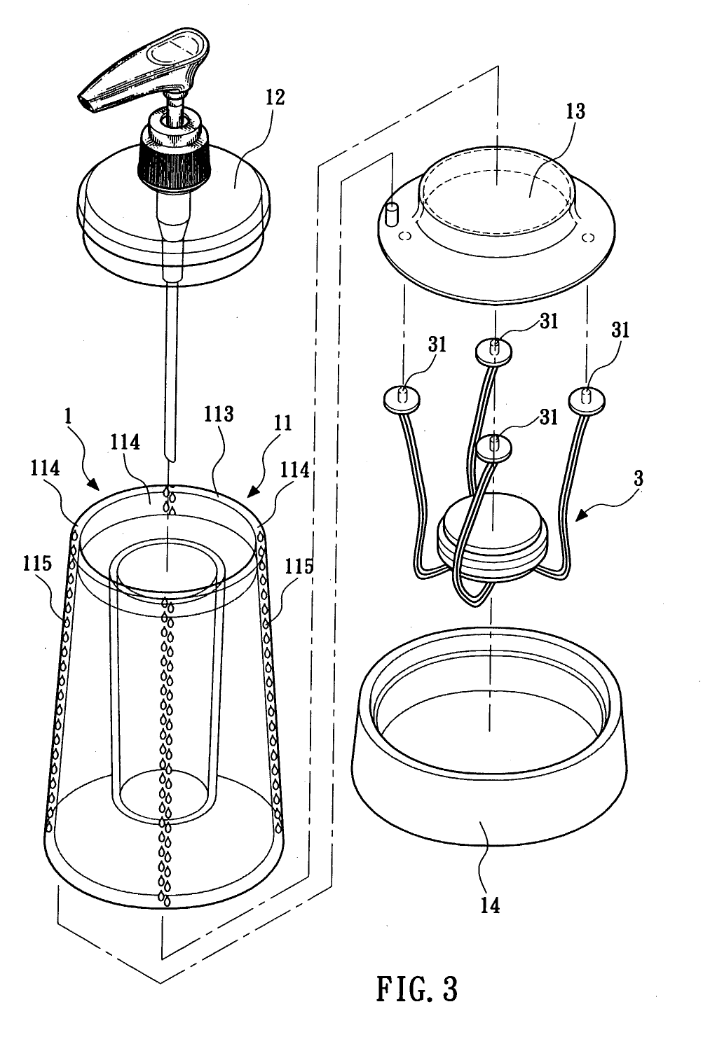

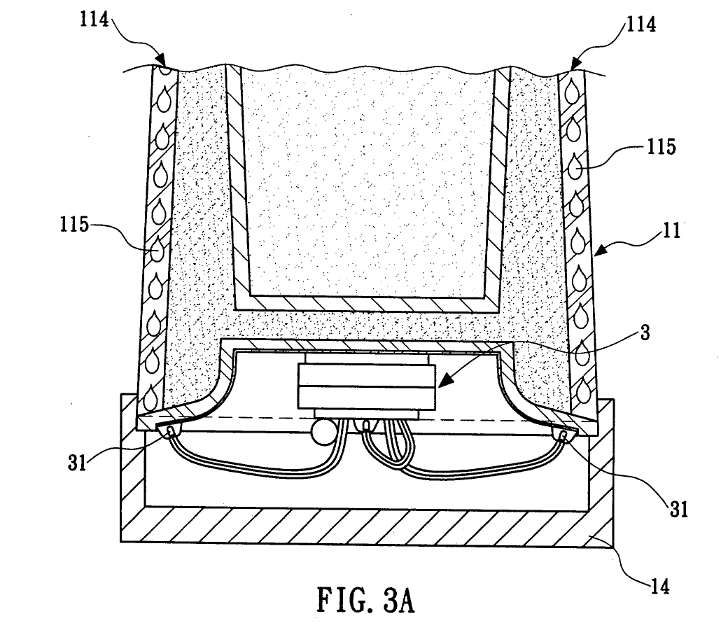

FIGS. 3 and 3A are exploded perspective and fragmentary sectional views, respectively, of a liquid-ornamented milky lotion bottle 1 having an illuminating structure according to a third embodiment of the present invention. The milky lotion bottle 1 is structurally similar to that shown in FIGS. 1 and 1A to 1C. That is, the bottle 1 has a body 11 manufactured with a transparent plastic material, such as acrylic resin, by way of integral injection molding. The illuminating structure in the third embodiment includes a plurality of rows 114 of lengthwise-extended air bubbles 115 directly formed on an outer wall 113 of the body 11 when the body 11 is injection-molded, and a light-emitting device 3 including a plurality of light-emitting diodes (LEDs) 31 and related electronic elements (not shown) located in a base 14 that is connected to a lower side of a bottom cover 13 of the body 11. In the illustrated milky lotion bottle 1 of the third embodiment, there are four bubble rows 114 spaced along the outer wall 113 to function like light-conducting bodies, and the LEDs 31 are separately in alignment with lower ends of the bubble rows 114. When the LEDs 31 are turned on, light emitted therefrom is directly upward projected onto the bubble rows 114 via lower end surfaces thereof, so that luminous spots or surfaces are produced on air bubbles 115 in the bubble rows 114, creating unique and novel decorating effect on the liquid-ornamented milky lotion bottle 1.

The present invention has been described with some preferred embodiments thereof and it is understood that many changes and modifications in the described embodiments can be carried out without departing from the scope and the spirit of the invention as defined by the appended claims.

What is claimed is:

1. A liquid-ornamented article having an illuminating structure, comprising at least one closed chamber made of a transparent plastic material by way of injection molding and supersonic welding for containing at least one type of liquid ornament, such as an amount of mono-liquid or dual-liquid with or without one or more floating ornaments, and an illuminating structure; said illuminating structure including a plurality of light-conducting bodies fixedly provided in said at least one closed chamber with one end of said light-conducting bodies pressed against an inner surface of a wall portion of said at least one closed chamber, and a light-emitting device mounted in a base that is connected to an outer side of said wall portion in contact with said one end of said light-conducting bodies; said light-emitting device including a plurality of light-emitting diodes (LEDs) separately located in said base corresponding to said light-conducting bodies, so that light emitted from said LEDs is directly projected into said light-conducting bodies via said one end thereof to produce luminous spots or surfaces on said light-conducting bodies and thereby creates a luminous decorating effect on said article.

2. The liquid-ornamented article having an illuminating structure as claimed in claim 1, wherein said article is a milky lotion bottle having a container formed from a body, a top cap, and a bottom cover, all of which being made of a transparent plastic material byway of integral injection molding, said at least one closed chamber being formed through connecting said bottom cover to said body by way of supersonic welding; said a plurality of light-conducting bodies being pressed at lower ends against an inner surface of said bottom cover, and said base being connected to a lower side of said bottom cover, so that said LEDs are located corresponding to lower ends of said light-conducting bodies for light emitted therefrom to directly project onto said lower ends of said light-conducting bodies.

3. The liquid-ornamented article having an illuminating structure as claimed in claim 1, wherein said article is a tooth glass including a container having a body divided into separated upper and lower chambers and a bottom cover, both of said body and said bottom cover being made of a transparent plastic material by way of integral injection molding; said at least one closed chamber being formed through connecting said bottom cover to said lower chamber of said body by way of supersonic welding; said a plurality of light-conducting bodies being pressed at lower ends against an inner surface of said bottom cover; and said base being connected to a lower side of said bottom cover, so that said LEDs are located corresponding to lower ends of said light-conducting bodies for light emitted therefrom to directly project onto said lower ends of said light-conducting bodies.

4. The liquid-ornamented article having an illuminating structure as claimed in claim 1, wherein said light-conducting bodies are plastic optical fibers, which are tied together at one end to form at least one bundle having one flat-headed end, and said flat-headed end of said at least one bundle of said light-conducting bodies being located corresponding to said LEDs for light emitted from said LEDs to directly project onto said flat-headed end of said at least one bundle of said plastic optical fibers.

5. The liquid-ornamented article having an illuminating structure as claimed in claim 1, wherein said light-conducting bodies are light-pervious plastic pipes having a plurality of air bubbles lengthwise formed therein by way of plastic injection-molding technique, and said light emitted from said LEDs and projected onto one end of said plastic pipes facing toward said LEDs produces luminous spots or surfaces on said air bubbles.

6. A liquid-ornamented article having an illuminating structure, comprising at least one closed chamber made of a transparent plastic material by way of injection-molding and supersonic welding for containing at least one type of liquid ornament, such as an amount of mono-liquid or dual-liquid with or without one or more floating ornaments, and an illuminating structure; said illuminating structure including a plurality of rows of lengthwise-extended air bubbles directly formed on an outer wall of said closed chamber when said closed chamber is injection-molded, and a light-emitting device located in a base that is connected to an outer side of said at least one closed chamber, said light-emitting device including a plurality of LEDs that are separately in alignment with an end of said a plurality of rows of air bubbles, so that light emitted from said LEDs is directly projected onto said one end of said rows of air bubbles to produce luminous spots or surfaces on air bubbles in said bubble rows, and thereby creates a luminous decorating effect on said article.
